(19) United States
(12) Patent Application Publication
(10) Pub. No.: US 2003/0160149 A1
(43) Pub. Date: Aug. 28, 2003

(54) METHOD AND APPARATUS FOR REAL TIME SYNCHRONOUS CONTROL OF LASER BEAMS AND MULTI-AXIS MACHINES

(76) Inventors: Patrick H. Dwyer, Penn Valley, CA (US); Gordon R. Southam, Grass Valley, CA (US)

Correspondence Address: Patrick H. Dwyer, Aim Controls, Inc. # 114, 10138 Commercial Avenve, Penn Valley, CA, 95946, US

(21) Appl. No.: 10/082,633

(22) Filed: Feb. 22, 2002

(51) Int. Cl. H01L 27/00

(52) U.S. Cl. 250/208.1

(57) ABSTRACT

An apparatus and method for the control of laser beams in real time synchronization with the control of multi-axis machines that position laser beams in two or three dimensional space, including the positioning of a laser beam with respect to the object(s) to be affected, the timing of when the laser is turned on and off, and the amount of laser light produced when the laser is on. The apparatus consists of digital electronic circuitry to control the laser and the motion of each axis in a multi-axis machine. The digital electronic circuitry synchronizes the laser operation with the multi-axis movement by means of real time digital electronic synchronization signals between the motion control circuitry and the laser control circuitry. There is also non-real time software that handles image processing on an external computer and real time embedded software running on a microprocessor connected to the digital electronic circuitry that operates to covert commands and data from the image processing software into bit register information that is processed by the motion control circuitry and the laser control circuitry.

### CROSS-REFERENCE TO RELATED APPLICATIONS

Not Applicable

### STATEMENT REGARDING FEDERALLY SPONSORED RESEARCH OR DEVELOPMENT

Not Applicable

### REFERENCE TO A MICROFICHE APPENDIX

Not Applicable

### SMALL ENTITY STATUS CLAIMED

### BACKGROUND OF THE INVENTION

1. Field of the Invention

This invention pertains to the control of laser beams in real time synchronization with the control of multi-axis machines that position laser beams in two or three dimensional space. There are three primary elements to such synchronous control: (a) the positioning of the laser beam with respect to the object(s) to be affected; (b) the timing of when the laser is turned on and off; and (c) the amount of laser light produced when the laser is on.

The invention is comprised of a digital electronic control system that operates multi-axis machines and lasers in a real time, synchronous manner to achieve such purposes. Compared to existing control systems, it is more accurate, simpler to integrate with the multi-axis machine and control computer, and lower in cost.

2. Description of the Background Art

There are a variety of electronic control systems that have been developed for the control of laser beams in multi-axis machines such as X, Y tables and/or two axis galvonometer type laser scanning heads. The following is a description of a typical example of the present art in the field.

First, there is a computer (typically a personal computer) on which there is a non-real time software program that processes the pixel data in an input image file into position coordinates to be sent to the multi-axis machine and laser on/off power level information for the laser power supply.

Second, there is an electronic hardware circuit on a “motor controller plug in card” (or equivalent) that can be memory addressed by the non-real time software and to which the position coordinates and motor commands (e.g., velocity, acceleration) are sent. This motor controller card contains circuitry to translate the position bit information developed by the software into electronic control signals for driving the motors on the multi-axis machine. There will then be a cable(s) running from the motor controller card to an external motor power driver circuit board(s) that actually provides the power signals to the motor.

Third there is an electronic hardware circuit on a “laser controller plug in” card (or equivalent) that can be memory addressed by the non-real time software and to which the laser on/off and power level information is sent. This laser controller card contains circuitry to translate the on/off power level bit information developed by the software into electronic control signals for driving the laser power supply. There will then be a cable(s) running from the laser controller card to an external laser power supply that actually provides the power to the laser.

Fourth, there is an electronic hardware circuit on a “encoder plug in” card (or equivalent) that can be memory addressed by the non-real time software and to which the external position encoders, or other positioning device(s), send position information about the actual position of each axis of the machine. This encoder card contains circuitry to translate the position signals developed by the encoders into bit information that the non-real time software can use to compare the actual position (as determined by the encoders) with the position calculated by the non-real time software.

Fifth, there may be an electronic hardware circuit on a “input/output plug in” card (or equivalent) that can be memory addressed by the non-real time software and to which external control signals from limit switches, photo transistors, lights, relays, and similar devices send and receive information about status of the multi-axis machine and/or laser. This input/output card contains circuitry to translate the electrical signals to and from the external input/output devices into bit information that the non-real time software can use to determine if limits have been exceeded or to turn on/off warning lights or to actuate other devices on the multi-axis machine.

The foregoing is meant to be an example of a typical system. Some of the specific aspects may vary from system to system, such as the combination of one or more of the electronic hardware circuits onto one plug in card or into an external package. However, the main operating feature of such systems is that the synchronization and timing of the various electronic input and output signals is done primarily by the non-real time software on the computer. In particular, there are no direct, electronic synchronization signals between the circuits for motor control and the circuits for laser power control. Consequently, the non-real time software must use algorithms to predict when each axis will be at the right position to turn on/off the laser (as well as the power level). Moreover, the predicting of the future position of each axis is further complicated by the non-real time software's task of having to read the position feedback encoders, compare that position to the previously calculated (estimated) position, and then in turn, add or subtract an appropriate value to correct for error in the future position.

The amount of time it takes for the electrical signals to and from all of the various external electronic components on the multi-axis machine to travel to and from the computer, plus the time it takes for the non-real time software to transmit and receive all of these signals to and from the various plug in cards, plus the amount of time it takes the non-real time software to perform the necessary computations and then output new information, is know as the amount of “latency” in the system. In such complex systems as laser beam controllers for multi-axis machines the amount of system latency can be considerable. Thus, there is always an inherent uncertainly in such a system and a corresponding amount of error.

In addition to the latency in such a system, there is a considerable quantity of electronic circuitry to interconnect (often from different manufactures), which increases the cabling requirements, and the need for a computer with considerable processing speed and power. Moreover, there may actually be separate non-real time software systems (from different companies) running on the main control computer that operate the different electronic hardware circuits: for example, there may be an image processing software system, a motor control software system, and a laser power software system, all of which must be integrated by the user.

### BRIEF SUMMARY OF THE INVENTION

Applicant's invention utilizes a novel design concept that begins with the complete integration of all of the electronic hardware for the control of the motors, laser power supply, and all input and output devices into a single digital electronic package (or even a single integrated circuit) wherein the synchronization of all of the important real time operations, especially the motor position and the laser on/off power level signals, are done with digital electronic circuitry instead of software. The only operations done by the software on the external control computer is the image processing of the input file to obtain two or three dimension position coordinates, laser on/off power levels, and motion commands. These operations do not need to be done in a real time manner and these data and commands are sent to applicant's digital electronic circuitry on a non-real time basis where it is stored (buffered) in digital memory circuits. Then, the real time digital electronic circuitry can process the data and commands, when needed, into the critical real time motor position and laser power level signals.

The primary advantages of applicant's invention are: (a) the substantial reduction of the error between the calculated position and laser power level and the actual operating position and laser power level for a given pixel (“pixel” being used here to define a point or small area in a computerized image file of either two or three dimensions for which a corresponding position and laser on/off power level must be projected onto the object(s) to be affected); (b) the simplification of the image processing software (typically personal computer based) required to translate input image file pixel data into output commands and data to operate the multi-axis machine and laser power supply; (c) the substantial reduction of the cabling between the computer system (running the image processing software) and the electronic hardware to drive the multi-axis machine and laser power supply; (d) the elimination of specially designed “add-on” electronic hardware cards for the computer system (running the image processing software); and (e) a substantial reduction in cost.

The electronic hardware portion of Applicant's invention consists of an integrated digital electronic system that can be divided into two main parts: digital circuitry to control the laser power supply, hereafter referred to as the “Laser Control Circuit”, and digital circuitry to control the motion in a multi-axis machine, hereafter referred to as the “Motion Control Circuit”. Although these are discussed as two separate circuits for purposes of disclosing the invention, such circuits in a preferred embodiment would be physically combined into one electronic package or a single integrated circuit. The principle of operation would remain the same. The number and nature of the axes to be controlled can also vary from 1 to N, but is typically 2 to 4. A typical example would be an X, Y position table or an X, Y table with an additional two axes for control of a scanning head such as a galvonometer. Other combinations of an X, Y table with a rotary table or spindle are relatively common. In all such cases the problem is the same: the synchronization of the laser power level for a given pixel with the corresponding two or three dimensional laser beam position coordinate for that pixel.

The software portion of Applicant's invention consists of two parts: non-real time software that handles image processing on an external computer, hereafter referred to as the “Image Processing Software”; and real time software that operates on an embedded microprocessor interfaced with the Motion Control Circuitry to control the multi-axis machine motion, hereafter referred to as the “Embedded Control Software”. It should be noted here that all or part of the Embedded Control Software could also be converted into electronic hardware that would become part of the Motion Control Circuit and/or Laser Control Circuit. What portion of the “logic” that remains as the Embedded Control Software” and what portion that is converted into digital electronic circuitry is merely a matter of where to “draw the line” between the two. This depends primarily upon the complexity and cost of the conversion versus the resultant benefits in cost, ease of design, flexibility, and other related items.

The Image Processing Software can be compiled to operate on almost any kind of digital computer, but is most likely to be used with a personal computer. The Image Processing Software takes an image file (typically a “bitmap” type) as its data input and processes each pixel of the input file to extract a laser on/off and power level value for each pixel and a corresponding X, Y (or other axis) two or three dimension position value for each pixel. Upon command from the user, the Image Processing Software then sends to the Laser Control Circuit the laser on/off power level data and sends to the Motion Control Circuit, via the Embedded Control Software, an appropriate motion command with two or three dimension position data for each axis of laser beam motion.

The Embedded Control Software can be compiled to operate on a variety of microprocessors, but is most likely to be used on a microprocessor with at least 16 bit processing capability. The Embedded Control Software receives the motion command and position data from the Image Processing Software, computes the correct velocity and acceleration information for each axis of motion, and then sends to the Motion Control Circuit the requisite bit register level commands and data. The Motion Control Circuit, in turn, generates all of the motor driver signals for each axis which determines the velocity, acceleration and position of each axis and also generates the timing signals to synchronize the motor driver signals (typically a pixel sync pulse and a pixel direction or position indicator) with the with the laser on/off power level signals sent from the Laser Control Circuit to the Laser Beam Power Supply.

The Laser Control Circuit is responsible for storing and processing the on/off and power level data received from the Image Processing Software into discrete signals that are sent to the Laser Beam Power Supply. These output signals can be formatted to drive a variety of different laser types using such means as pulse width modulation or bit register data for a digital to analog converter. The Laser Control Circuit is also responsible for processing real time (typically TTL) input and output signals from and to external safety devices such as manual interlock switches and warning lights to prevent the laser beam from being turned on when the machine operator is not ready.

The Motion Control Circuit is responsible for processing the multi-axis (typically X and Y, but additional axes are possible for scanning heads, rotary table, spindles, etc.) motion commands position data into motor velocity, acceleration, and position signals (per axis). The Motion Control Circuit simultaneously generates electronic timing signals that are directly connected to the Laser Control Circuit so that the Laser Control Circuit output signal to the Laser Power Supply (on/off and power level) for a given pixel is exactly synchronized with the corresponding two or three dimensional position coordinates.

The Motion Control Circuit can also decode and process input signals from a position encoder (e.g, a quadrature signal or an analog signal) to verify that the actual position of a given axis versus its computed position. Then the Embedded Control Software and the Motion Control Circuit can make any necessary corrections to a particular axis of motion.

The object of the invention is to provide the apparatus and method to control laser beams in real time synchronization with the control of multi-axis machines that position laser beams in two or three dimensional space, including: the positioning of the laser beam with respect to the object(s) to be affected; the timing of when the laser is turned on and off; and the amount of laser light produced when the laser is on. Further objects and advantages of the invention will be brought out in the following portions of the specification, wherein the detailed description is for the purpose of fully disclosing preferred embodiments of the invention without placing limitations thereon.

### BRIEF DESCRIPTION OF THE DRAWINGS

The invention will be more fully understood by reference to the following drawings which are for illustrative purposes only:

FIG. 1 is a diagrammatic representation of the overall control system for the laser and multi axis machine.

FIG. 2 is a diagrammatic representation of the image processing software used on a external computer to process the input image file into useable commands and data for position coordinate, axis motion, and laser power levels.

FIG. 3 is a diagrammatic representation of the embedded control software operating on an embedded microprocessor to process commands and data from the image processing software into bit level register commands and data to be used by the motion control laser control circuits.

FIG. 4 is a diagrammatic representation of the motion control circuit used to create the motor driver electrical signals for each axis of motion from the position coordinate data and commands received from the embedded control software.

FIG. 5 is a diagrammatic representation of the laser control circuit used to create the laser on/off and power level signals from the laser on/off power level data created by the image processing software.

### DETAILED DESCRIPTION OF THE INVENTION

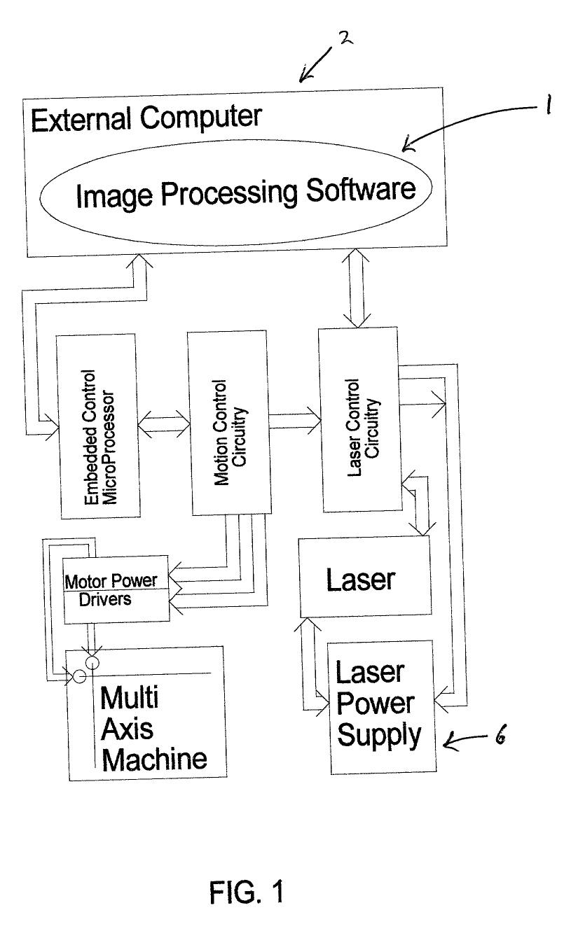

Referring more specifically to the drawings, for illustrative purposes the present invention is embodied in the apparatus generally shown in FIG. 1 through FIG. 5. It will be appreciated that the apparatus may vary as to configuration and as to details of the parts, and that the method may vary as to details and the order of the steps, without departing from the basic concepts as disclosed herein.

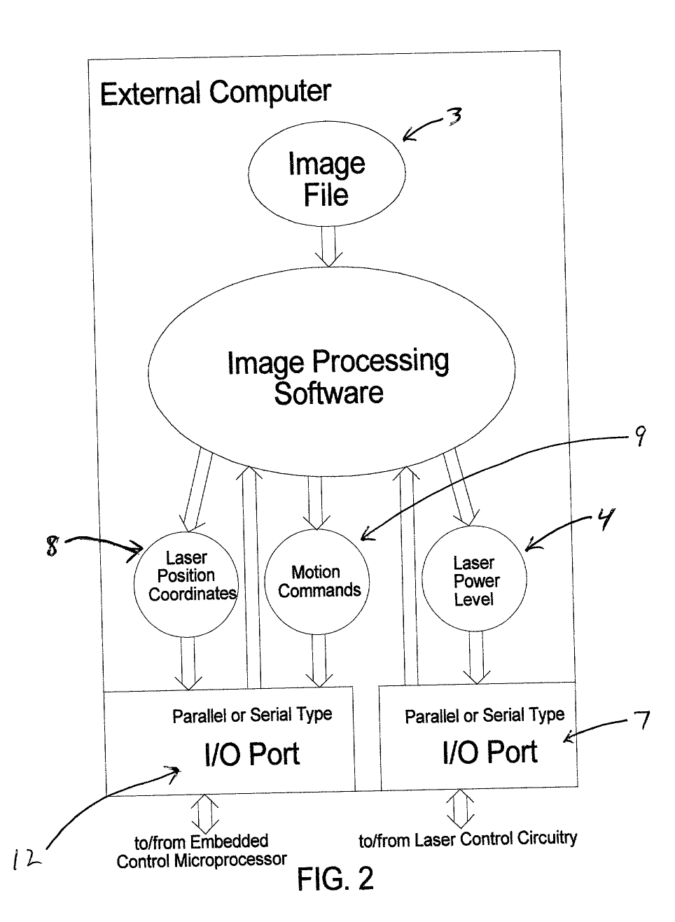

Referring to FIGS. 1 and 2, the Image Processing Software 1, operating on an external computer 2 takes an Image File 3 (typically a “bitmap” type) as its data input and processes the Image File 3 to obtain a Laser Power Level 4 for each pixel. As used herein, “pixel” refers to a representational point or small area of two or three dimensional space in an Image File. The Image Processing Software 1 then either stores each Laser Power Level 4 in a file on the external computer 2 and/or sends the Laser Power Level 4 to the Laser Control Circuit 5, as needed to operate the Laser Power Supply 6 via a standard parallel or serial type port 7.

Referring to FIGS. 1 and 2, the Image Processing Software 1 also computes two or three dimensional Laser Position Coordinates for each pixel in the Image File 3. The Image Processing Software 1 also determines, based upon the nature of the multi-axis control function specified by the user (e.g., raster scan, vector movement), what Motion Commands 9 (such as set velocity, set acceleration, or move specified distance) need to be sent to each axis of motion. The Image Processing Software 1 sends the Laser Position Coordinates 8 and the Motion Commands 9 to the Motion Control Circuit 10 via the Embedded Control Software 11.

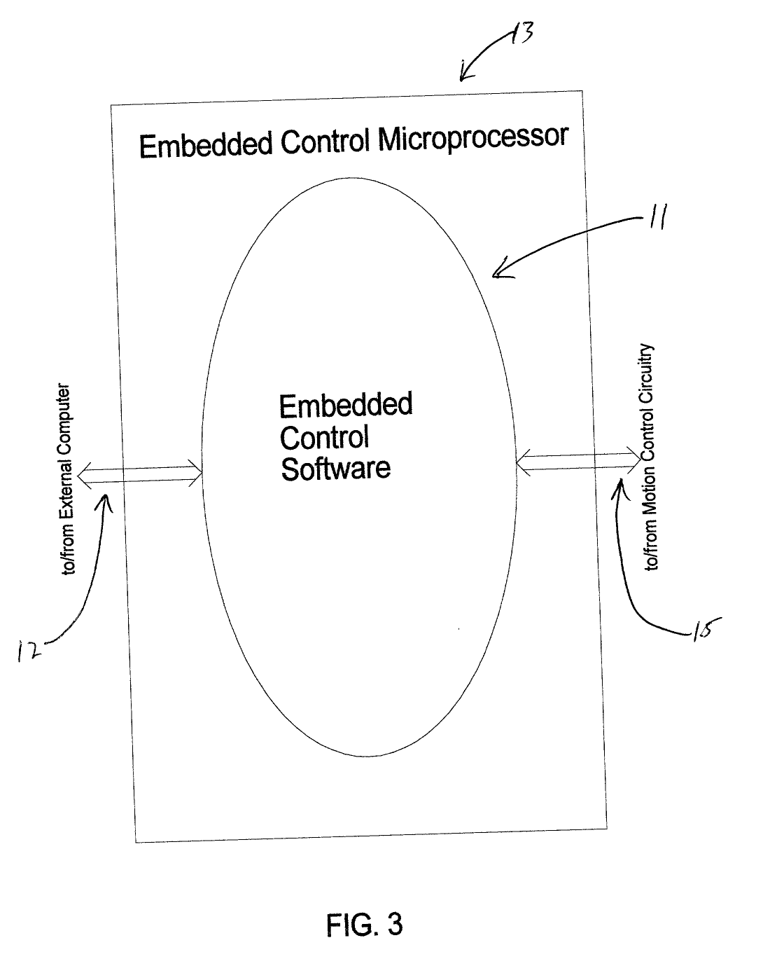

Referring to FIGS. 1 and 3, the Embedded Control Software 11 communicates with the Image Processing Software 1, receiving the Laser Position Coordinates 8 and the Motion Commands 9, and outputs the operational status back to the Image Processing Software 1 via standard serial or parallel type ports 12. The Embedded Control Software 11, which can be used with almost any Embedded Microprocessor 13, is responsible for translating the Laser Position Coordinates 8 and the Motion Commands 9 into bit register values that are transferred into the Command and Data registers 14 in the Motion Control Circuit 10. The Embedded Microprocessor is connected to the Motion Control Circuit by means of a standard address and data bus 15.

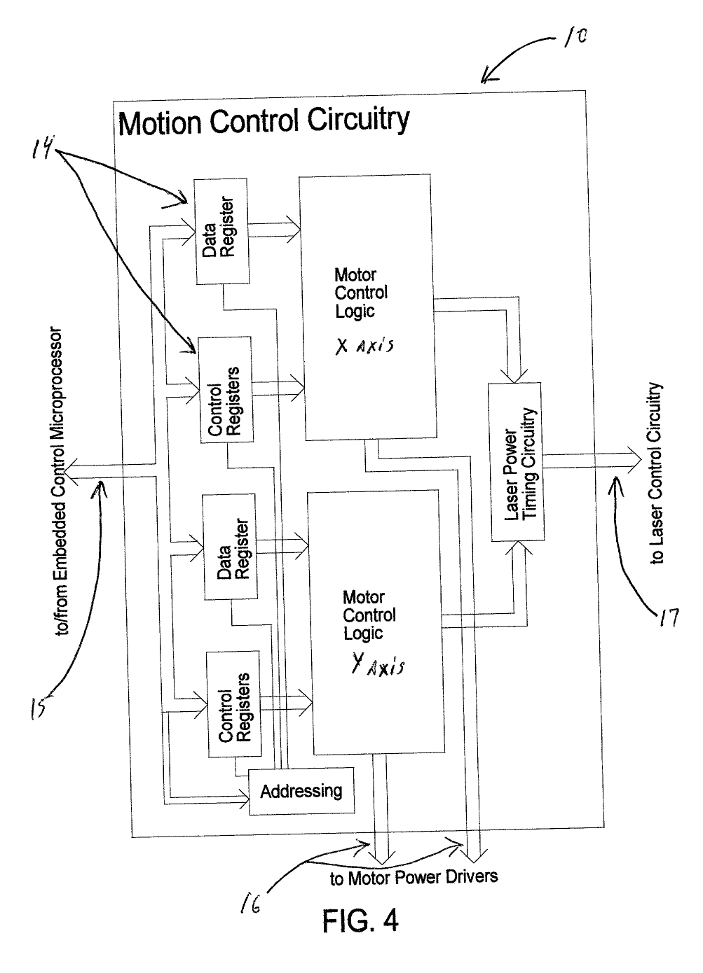

Referring to FIGS. 1 and 4, the Motion Control Circuit 10 takes the bit register values sent by the Embedded Control Software 11 to the Command and Data Registers 14 (that are memory mapped into the Embedded Control Processor's Memory Space) and generates: (a) the Motor Driver Signals 16 for each axis; and (b) the Laser Power Timing Signals 17 that are sent to the Laser Control Circuit 5 to synchronize the Motor Driver Signals 16 with the Laser Power Level Signals 18.

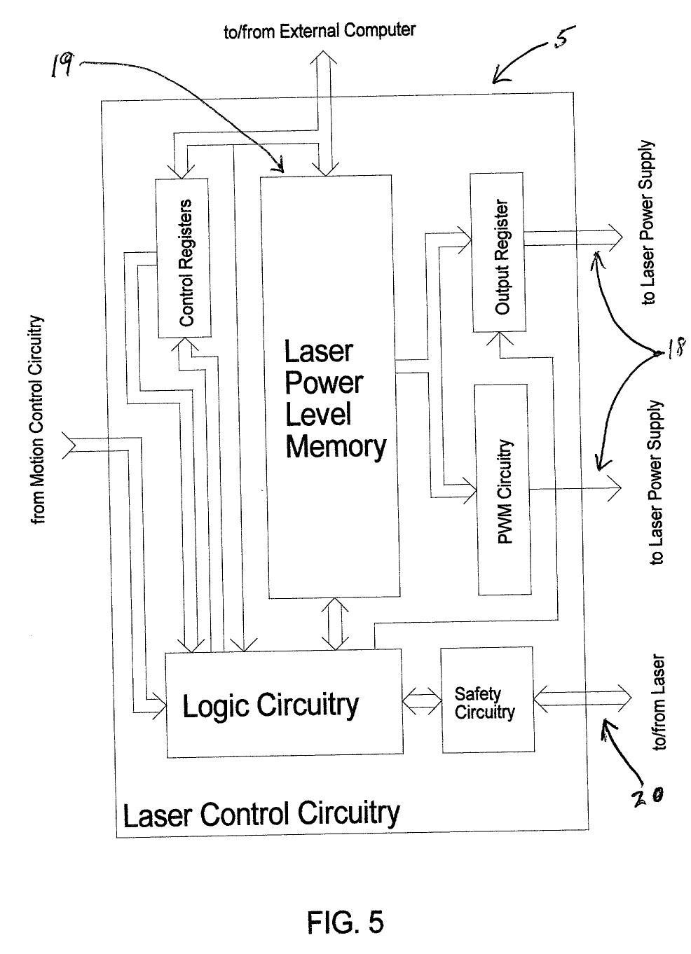

Referring to FIGS. 1 and 5, the Laser Control Circuit 5 receives in bit register form the Laser Power Level 4 from the Image Processing Software 1 and stores these values in the Laser Power Level Memory 19. When the Laser Control Circuit 5 receives the appropriate Laser Power Timing Signals 17 from the Motion Control Circuit 10, the Laser Control Circuit 5 converts the corresponding Laser Power Level 4 stored in Laser Power Level Memory 19 into the desired signal format and then outputs the correct Laser Power Level Signal 18 to the Laser Power Supply 6. It may be noted here that different laser power supplies have different types of input signal requirements to operate the particular laser and the invention disclosed here can be modified by anyone skilled in the art of electronic circuits to adapt the Laser Power Level Signal 18 to the required format such as an 8 bit register value or into a pulse width modulated TTL signal. The Laser Control Circuit also sends Safety Output Signals 20 to external safety devices such as warning lights and receives Safety Input Signals 20 from external safety manual interlock switches and to prevent the laser beam from being turned on when the machine operator is not ready. It may be noted here that different lasers may have different types of safety signal requirements and the invention disclosed here can be modified by anyone skilled in the art of electronic circuits to accommodate any required variation in input and output safety signals.

Although the description above contains many specificities, these should not be construed as limiting the scope of the invention, but merely as providing illustrations of some of the presently preferred embodiments of this invention. Thus, the scope of this invention should be determined by the appended claims and their legal equivalents.

What is claimed is:

1. An apparatus for the control of a laser in real time synchronization with the control of a multi-axis machine that positions said laser in two or three dimensional space, comprising:
(a) image processing software operating on an external computer, said image processing software computing a laser power level and a two or three dimensional position coordinate for each pixel in an input image file, and further, and said image processing software computing the commands to operate said multi-axis machine to position a laser beam corresponding to said two or three dimensional position coordinates and the commands to operate said laser synchronously with said multi-axis machine; and
(b) embedded control software operating on an embedded microprocessor, said embedded control software receiving said two or three dimensional position coordinates and said commands, outputting operational status back to said image processing software, converting said two or three dimensional position coordinates and said commands into bit register values, and outputting said two or three dimensional position coordinates and said commands as said bit register values on a microprocessor data and address bus; and
(c) digital electronic circuitry, said digital electronic circuitry being able to:
(i) receive, store, and process said bit register values for power levels for said laser, each said power level corresponding to a said two or three dimensional position coordinate; and
(ii) receive, store, and process said bit register values for each said two or three dimensional position coordinate for said multi-axis machine; and
(iii) receive, store, and process said bit register values for said commands to control said multi-axis machine; and
(iv) generate the motor drive signals for each axis of said multi-axis machine so as to position each axis of said multi-axis machine; and
(v) generate from said power levels for said laser the signals to control the power supply of said laser; and
(vi) generate electronic signals that synchronize in real time the said power levels for said laser with the said two or three dimensional position coordinates for said multi-axis machine; and
(vii) receive, store and process position feedback information from each axis of said multi-axis machine, compare said position feedback information with the said two or three dimensional position coordinates, and then make any necessary corrections in the said motor drive signals to correct any error between said position feedback information and said two or three dimensional coordinates; and
(viii) receive, store and process electronic signals to and from safety devices, including interlock switches and indicator and warning lights, on said multi-axis machine and said laser.

2. A method for the control of a laser in real time synchronization with the control of a multi-axis machine that positions said laser in two or three dimensional space, two or three dimensional space, comprising the steps of:
(a) providing image processing software operating on an external computer, said image processing software computing a laser power level and a two or three dimensional position coordinate for each pixel in an input image file, and further, and said image processing software computing the commands to operate said multi-axis machine to position a laser beam corresponding to said two or three dimensional position coordinates and the commands to operate said laser synchronously with said multi-axis machine; and
(b) providing embedded control software operating on an embedded microprocessor, said embedded control software receiving said two or three dimensional position coordinates and said commands, outputting operational status back to said image processing software, converting said two or three dimensional position coordinates and said commands into bit register values, and outputting said two or three dimensional position coordinates and said commands as said bit register values on a microprocessor data and address bus; and
(c) providing digital electronic circuitry, said digital electronic circuitry:
(i) receiving, storing, and processing said bit register values for power levels for said laser, each said power level corresponding to a said two or three dimensional position coordinate; and
(ii) receiving, storing, and processing said bit register values for each said two or three dimensional position coordinate for said multi-axis machine; and
(iii) receiving, storing, and processing said bit register values for said commands to control said multi-axis machine; and
(iv) generating the motor drive signals for each axis of said multi-axis machine so as to position each axis of said multi-axis machine; and
(v) generating from said power levels for said laser the signals to control the power supply of said laser; and
(vi) generating electronic signals that synchronize the said power levels for said laser with the said two or three dimensional position coordinates for said multi-axis machine; and
(vii) receiving, storing and processing position feedback information from each axis of said multi-axis machine, compare said position feedback information with the said two or three dimensional position coordinates, and then make any necessary corrections in the said motor drive signals to correct any error between said position feedback information and said two or three dimensional coordinates; and
(viii) receiving, storing and processing electronic signals to and from safety devices, including interlock switches and indicator and warning lights, on said multi-axis machine and said laser.
